(19) United States
(12) Patent Application Publication
(10) Pub. No.: US 2011/0312185 A1
(43) Pub. Date: Dec. 22, 2011

(54) PATTERN FORMATION METHOD AND PATTERN FORMATION DEVICE

(76) Inventor: Yuriko SEINO, Yokohama-Shi (JP)

(21) Appl. No.: 13/051,788

(22) Filed: Mar. 18, 2011

(30) Foreign Application Priority Data
Jun. 18, 2010 (JP) 2010-139576

(51) Int. Cl. H01L 21/3105; B05C 13/02

(52) U.S. Cl. 438/703; 118/58; 257/E21.241

(57) ABSTRACT

According to one embodiment, a pattern formation method includes: forming a first pattern in a first region on a substrate to be treated; coating a plurality of types of block copolymers which are different in composition ratio on a second region which is different from the first region; and forming in the second region, by a heat treatment, a second pattern including a plurality of types of structures based on the coated plurality of types of block copolymers.

### CROSS-REFERENCE TO RELATED APPLICATION

This application is based upon and claims the benefit of priority from prior Japanese Patent Application No. 2010-139576 filed on Jun. 18, 2010 in Japan, the entire contents of which are incorporated herein by reference.

### FIELD

Embodiments of the present invention relate to a pattern formation method and a pattern formation device.

### BACKGROUND

As one of conventional technologies, there has been proposed a method, wherein, when performing CMP (Chemical Mechanical Polishing) and a processing on a film to be processed with the use of a resist pattern as a mask, the resist pattern is formed also on a region in a wafer peripheral region which is not usable as a chip so as to suppress a fluctuation in dimension caused by the CMP and the processing.

However, since an exposure processing is performed for the purpose of forming the resist pattern in the wafer peripheral region though the wafer peripheral region is not usable as a chip, the conventional method has problems of a throughput degradation and an increase in cost.

### BRIEF DESCRIPTION OF THE DRAWINGS

FIG. 1A is a top view showing a wafer according to a first embodiment;

FIG. 1B(a) is a block diagram showing a block copolymer according to the first embodiment, FIG. 1B(b) is a schematic diagram showing the block copolymer according to the first embodiment before self-organization, and FIG. 1B(c) is a schematic diagram showing the block copolymer according to the first embodiment after self-organization;

FIG. 2 is a schematic diagram showing a structure formed by microphase separation, a length of a polymer block chain, and a relationship between ratios of lengths of the two polymer block chains according to the first embodiment;

FIG. 3A to FIG. 3E are main part sectional views showing a production method of a semiconductor device according to the first embodiment;

FIG. 4(a) is a block diagram showing a shot lacking region on which a solution containing the block copolymer is dropped according to the first embodiment, FIG. 4(b) is a block diagram showing a structure which is formed in the shot lacking region according to the first embodiment, and FIG. 4(c) is a block diagram showing the shot lacking region after removal of PMMA according to the first embodiment;

FIG. 5A to FIG. 5E are main part sectional views showing a production method of a semiconductor device according to a second embodiment; and

FIG. 6(a) is a block diagram showing a shot lacking region on which a solution containing the block copolymer is dropped according to the second embodiment, and FIG. 6(b) is a block diagram showing a structure which is formed in the shot lacking region according to the second embodiment.

### DETAILED DESCRIPTION

According to one embodiment, a pattern formation method comprises: forming a first pattern in a first region on a substrate to be treated; coating a plurality of types of block copolymers which are different in composition ratio on a second region, the second region being different from the first region; and forming in the second region, by a heat treatment, a second pattern including a plurality of types of structures based on the coated plurality of types of block copolymers.

### First Embodiment

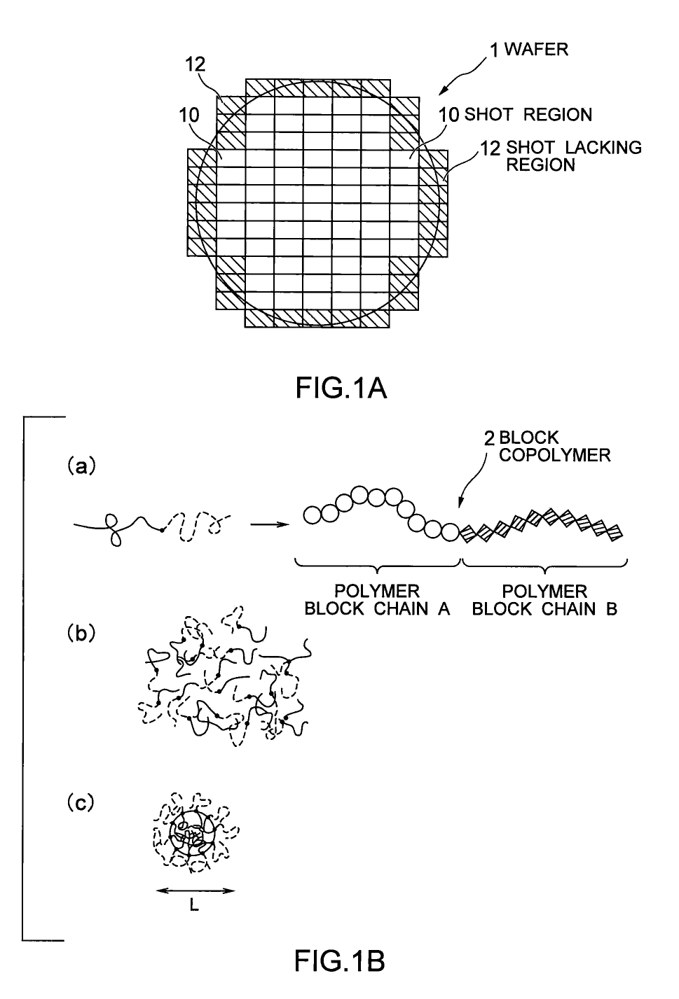

FIG. 1A is a top view showing a wafer according to a first embodiment. A wafer 1 which is a substrate to be treated is a semiconductor substrate including a Si-based crystal, for example, as a main component. For example, as shown in FIG. 1A, the wafer 1 has a plurality of shot regions (first regions) 10 on which devices can be formed and a plurality of shot lacking regions (second regions) 12, on which the devices cannot be formed in a part of chips since the shot lacking regions are positioned at a peripheral part. The shot lacking region 12 is indicated by hatching in FIG. 1A. The first region may be a device region which is determined to be defective in a region testing step or the like without limitation to the shot lacking region 12.

In the first embodiment, a method for forming a pattern by microphase separation of a block copolymer will be described.

Hereinafter, as a method of forming the pattern in the shot region 10, a nanoimprint method is employed. Accordingly, the shot region 10 is a region on which the pattern is formed by pressing thereto a template once.

It is known that a difference in finished dimension is caused between the shot region 10 and the shot lacking region 12 by a processing by RIE (Reactive Ion Etching), CMP, or the like when a covering ratio of the pattern in the shot region 10 and a covering ratio of the pattern in the shot lacking region 12 are different from each other.

As used herein, the term “covering ratio in the shot region 10” means a ratio between an area occupied by a pattern formed on the shot region 10 and an area of the shot region 10. Also, the term “covering ratio in the shot lacking region 12” means a ratio between an area occupied by the pattern formed on the shot lacking region 12 and an area of the shot region lacking 12.

In the present embodiment, a resist pattern (first pattern) is formed on the shot region 10 by coating a resist material. On the other hand, a block copolymer is coated on the shot lacking region 12 to form a pattern (second pattern) by self-organization of the block copolymer. Hereinafter, the block copolymer will be described.

### (Constitution of Block Copolymer)

FIG. 1B(a) is a block diagram showing a block copolymer according to the first embodiment. FIG. 1B(b) is a schematic diagram showing the block copolymer according to the first embodiment before self-organization. FIG. 1B(c) is a schematic diagram showing the block copolymer according to the first embodiment after the self-organization.

A block copolymer 2 is formed by linear chemical bonding between two different polymer block chains A and B as shown in FIG. 1B(a), for example. The two different polymer block chains A and B may preferably be those in which microphase separation is easily caused, such as polystyrene and polymethyl methacrylate, polystyrene and polydimethylsiloxane, polystyrene and polybutadiene, and polystyrene and polyisoprene.

In the present embodiment, PS (Polystyrene) is used as the polymer block chain A, and PMMA (Polymethyl Methacrylate) is used as the polymer block chain B. The block copolymer 2 may be those in which 3 or more types of polymer block chains are bonded. Also, the block copolymer 2 may be a star type in which one or more polymer block chain(s) radially extends from the center or a type in which a polymer block chain is suspended from a main chain of another polymer block chain.

The two polymer block chains A and B have a property of repelling each other like water and oil and separating from each other. However, since the two polymer block chains A and B in the block copolymer 2 are bonded to each other, they cannot be separated. As a result, when a heat treatment is performed, microphase separation from a disorganized state shown in FIG. 1B (b) to a self-organized state shown in FIG. 1B(a) occurs in the block copolymer 2. The block copolymer 2 forms a nanostructure having the size of L (for example, a several nanometers to a several hundreds of nanometers) which is substantially equal to the polymer block chain as shown in FIG. 1B(c) by the microphase separation.

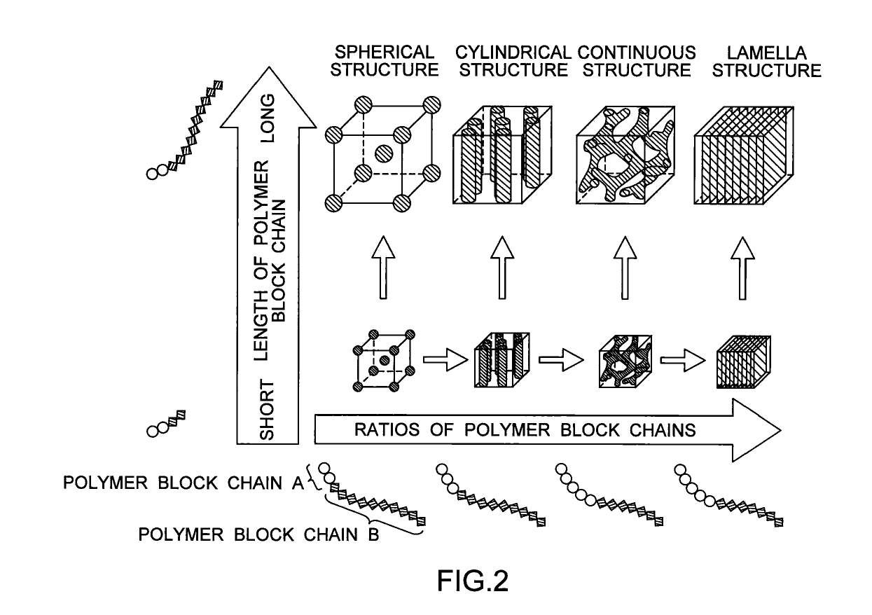

FIG. 2 is a schematic diagram showing the structure formed by the microphase separation according to the first embodiment, a length of the polymer block chain, and a relationship between ratios of lengths of the two polymer block chains.

The size of the structure generated by the microphase separation is decided depending on a length (molecular weight) of the polymer block chains. As shown in FIG. 2, the structure is small when the polymer block chain is short and is large when the polymer block chain is long. In the block copolymer 2, microphase separation to a spherical structure, a cylindrical structure, a continuous structure, or a lamella structure is caused by changing ratios (composition ratios) of the lengths of the two polymer block chains as shown in FIG. 2.

As used herein, the term “spherical structure” means a structure formed, for example, when polymer block chains of the smaller composition ratio are aggregated in the form of a sphere in the block copolymer 2.

The cylindrical structure is a structure formed when the polymer block chains of the smaller composition ratio are aggregated in the form of a column in the block copolymer 2.

The continuous structure is a structure formed, for example, when the polymer block chains of the smaller composition ratio are aggregated in the form of a three-dimensional lattice in the block copolymer 2.

The lamella structure is a structure formed, for example, when the composition ratios are equal to each other and by lamination of two phases alternately in the form of plane.

The polymer block chains forming the block copolymer 2 may preferably have a difference in etching rate. It is possible to remove one of the polymer block chains due to the etching rate difference.

The covering ratios when removing the polymer block chain of the smaller composition ratio are represented as the lamella structure<the continuous structure<the cylindrical structure<the spherical structure, for example. The covering ratio of the lamella structure is 50%. In contrast, the covering ratios when removing the polymer block chain of the larger composition ratio are represented as the spherical structure<the cylindrical structure<the continuous structure<lamella structure, for example.

In the case of preparing the lamella structure, a film formed from the block copolymer 2 may preferably have a film thickness of about 1.5 times of a pitch of alignment of PS and PMMA, for example. In the case of preparing the spherical structure or the cylindrical structure, a film formed from the block copolymer 2 may preferably have a film thickness substantially equal to a pitch of alignment of PS and PMMA, for example. Hereinafter, a method for producing a semiconductor device by using the block copolymer 2 will be described.

### (Semiconductor Device Production Method)

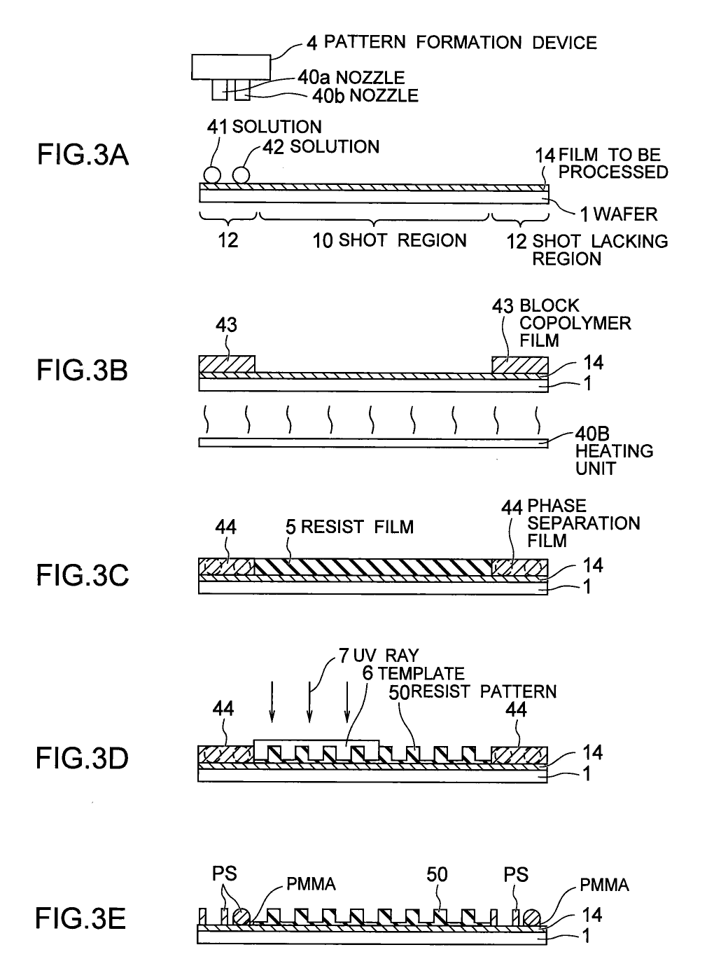

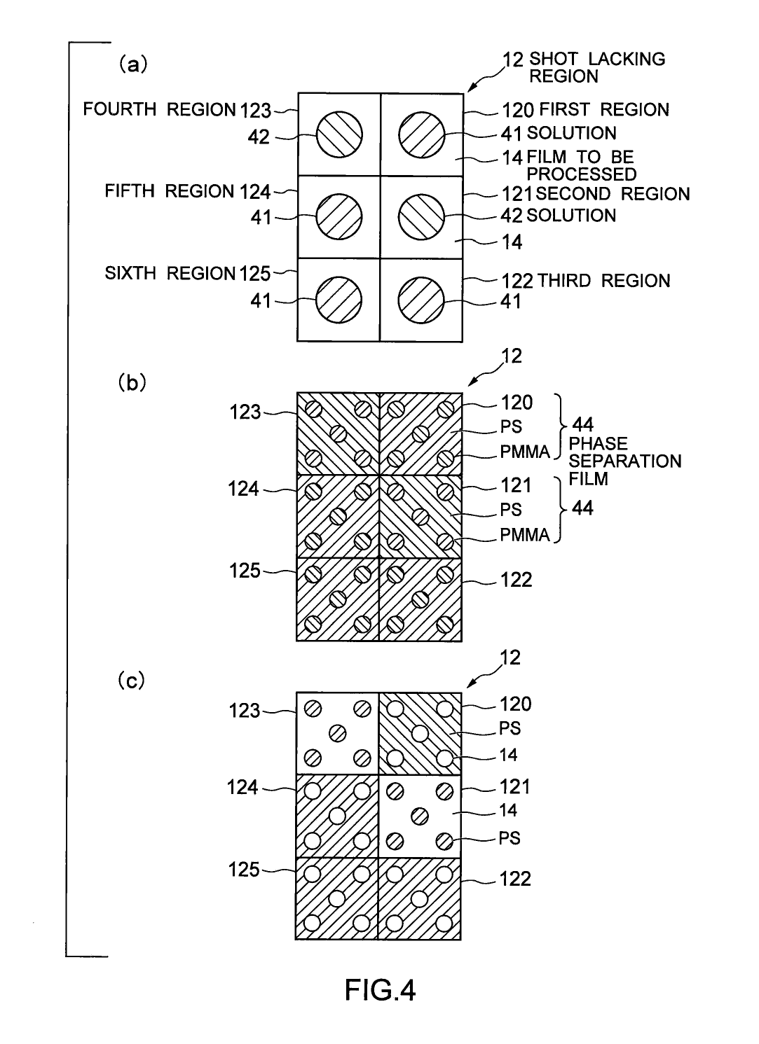

FIG. 3A to FIG. 3E are main part sectional views showing a semiconductor device production method according to the first embodiment. FIG. 4(a) is a block diagram showing a shot lacking region on which a solution containing the block copolymer is dropped according to the first embodiment. FIG. 4(b) is a block diagram showing a structure which is formed in the shot lacking region according to the first embodiment. FIG. 4(c) is a block diagram showing the shot lacking region after removal of PMMA according to the first embodiment. In each of the shot lacking regions 12 shown in FIGS. 4(a) to 4(c), at least one region of first to sixth regions 120 to 125 is lacking. The first region may be a device region which is determined to be defective in a region testing step or the like without limitation to the shot lacking region 12, and the first region is the shot lacking region 12 in the present embodiment.

In the present embodiment, a method of controlling the covering ratio of the shot lacking region 12 by using solutions 41 and 42 obtained by inverting compositions of PS and PMMA will be described. In the following embodiment, amounts of droplets to be emitted from a pattern formation device 4 are equal to one another. Also, in the following embodiments, a method of forming a resist pattern on the wafer 1 is the nanoimprint method using a template 6. A region on which the resist pattern is formed by using the nanoimprint method is a product region from which a product is obtained in a substrate to be treated, and the shot lacking region is a non-product region from which any product is not obtained in the substrate to be treated.

The pattern formation device 4 includes nozzles 40a and 40b and a heating unit 40B. The pattern formation device 4 is configured, for example, to supply the solution 41 to a target region by the nozzle 40a and then supply the solution 42 to a target region by the nozzle 40b.

To start with, the wafer 1 on which a film to be processed 14 is formed is prepared. Also, the two types of solutions 41 and 42 obtainable by inverting the compositions of PS and PMMA are prepared.

Each of the solutions 41 and 42 is obtained, for example, by dissolving a block copolymer into propylene glycol monomethyl ether acetate which is a solvent, and a concentration, a viscosity, and the like are adjusted so that the solutions 41 and 42 are emitted from the nozzles 40a and 40b of the pattern formation device 4.

In the solutions 41 and 42, for example, a PS homopolymer having a molecular weight (Mw) of 30000 is mixed with the block copolymer 2 formed of PS (Mw: 100000) and PMMA (Mw: 40000) to adjust mixing ratios of PS and PMMA so that the block copolymer 2 is easily dissolved into the solvent. The solution 41 has composition ratios of PS and PMMA of 80:20, for example. The solution 42 has composition ratios of PS and PMMA of 20:80, for example. It is preferable that the molecular weight of the block copolymer 2 is not changed by a large scale in order that the block copolymer 2 is mixed with the solvent when the composition ratios are inverted. Also, it is more preferable that the polymer block chains A and B of the block copolymer 2 have an identical molecular weight.

Subsequently, as shown in FIG. 3A, a plurality of droplets of 1 pL, for example, of each of the solutions 41 and 42 are supplied onto the shot lacking region 12, though the droplets of the solutions 41 and 42 are schematically shown as one droplet. A diameter of the solutions 41 and 42 is 1 μm, for example. The wafer 1 undergoes a hydrophobic treatment under HMDS (Hexamethyldisilazane) atmosphere at 180° C. for 60 seconds so that a surface energy of the film to be processed 14 is adjusted.

More specifically, the two types of solutions 41 and 42 are delivered by droplets so that the covering ratios of the shot region 10 and the shot lacking region 12 are equal to each other. As described above, one type of structure is generated by one combination of compositions, and the covering ratio is decided by the structure. In the case where the covering ratio of the shot region 10 is different from the covering ratio decided by the structure, it is impossible for the short region 10 and the shot lacking region 12 to have an identical covering ratio. However, with the use of the plurality of solutions having different composition ratios, it is possible to form a plurality of types of structures, thereby enabling to control the covering ratio of the shot lacking region 12. The covering ratio of the shot lacking region 12 is decided based on coating amounts and coating positions of the plurality of types of block copolymers. The covering ratio of the shot region 10 may be an average value of covering ratios of all of the shot regions 10 of the wafer 1 or may be a covering ratio of one of the shot regions 10. Also, the covering ratio of the shot lacking region 12 may be an average value of covering ratios of all of the shot lacking regions 12 of the wafer 1 or may be a covering ratio of one of the shot lacking regions 12. Further, the covering ratio of the shot region 12 may be decided based on the covering ratio of the shot region 10 which is adjacent to the shot lacking region 12.

With the use of the solution 41 having the composition ratios PS and PMMA of 80:20, PMMA is formed into spheres. In contrast, with the use of the solution 42 having the composition ratios of PS and PMMA of 20:80, PS is formed into spheres. In other words, it is possible to vary the covering ratios of the region onto which the two types of solutions 41 and 42 are delivered by droplets by removing PMMA which has the larger etching rate than PS. Accordingly, it is possible to control the covering ratio of the shot lacking region 12 to a desired covering ratio by delivering the solutions 41 and 42 by droplets depending on regions obtained by dividing the shot lacking region 12.

In the present embodiment, the shot lacking region 12 is divided into the first to sixth regions 120 to 125, for examples, as shown in FIG. 4(a), and the solution 41 having the composition ratios of PS and PMMA of 80:20 is delivered by droplets onto the first, third, fifth, and sixth regions 120, 122, 124, and 125. Also, the solution 42 having the composition ratios of PS and PMMA of 20:80 is delivered by droplets onto the second and fourth regions 121 and 123.

Subsequently, the solutions 41 and 42 delivered by droplets are spread on the shot lacking region 12. More specifically, the solutions may be spread on the shot lacking region 12 by pressing the template 6 or by rotating the wafer 1. When the solutions 41 and 42 are spread, a block copolymer film 43 is formed on the shot lacking region 12. A film thickness of the block copolymer film 43 is 40 nm, for example.

Subsequently, a heat treatment is performed on the wafer 1 by a heating unit 40B as shown in FIG. 3B. The heat treatment is performed under nitrogen atmosphere at 220° C. for several minutes.

By the heat treatment, microphase separation is caused in the block copolymer film 43, and a phase separation film 44 is formed as shown in FIG. 4(b). A pattern caused by PS and PMMA is generated in the phase separation film 44. In the phase separation film 44 formed of the solution 41, PMMA is in the form of spheres each having a diameter of 40 nm, for example. The diameter of the sphere of PMMA is identical to a film thickness of the phase separation film 44, for example. Also, in the phase separation film 44 formed of the solution 42, PS is in the form of spheres each having a diameter of 40 nm, for example. The diameter of the sphere of PS is identical to the film thickness of the phase separation film 44, for example.

Subsequently, a resist material is coated on the shot region 10 to form a resist film 5 as shown in FIG. 3C. The resist material is a material which is cured by irradiation with UV ray, for example. A dotted circle of the phase separation film 44 shown in FIG. 3C schematically indicates the sphere generated by the microphase separation.

Subsequently, a resist pattern 50 is formed by the nanoimprint method as shown in FIG. 3D. More specifically, for example, the resist pattern 50 is formed by pressing the template 6 to the resist film 5 and irradiating the resist film 5 with UV ray 7 via the template 6 to cure the resist film 5.

Subsequently, PMMA of the phase separation film 44 is removed by dry etching as shown in FIG. 3E and FIG. 4(c). More specifically, dry etching by using an oxygen gas is performed. Here, PMMA which has a larger etching rate to the oxygen gas is removed, and PS mainly remains on the film to be processed 14.

In other words, as shown in FIG. 4(c), in the first, third, fifth, and sixth regions 120, 122, 124, and 125 onto which the solution 41 is delivered by droplets, PMMA which is in the form of spheres is removed. When PMMA which is in the form of spheres is removed, PS under the PMMA is also removed, for example, so that cylindrical openings are formed as shown in FIG. 3E and FIG. 4(c).

Also, in the second and fourth regions 121 and 123 onto which the solution 42 is delivered by droplets, PMMA is removed while remaining PS which is in the form of spheres. Since PMMA under the PS is hardly etched due to a mask of the spherical PS, for example, as shown in FIG. 3E, PMMA remains on the film to be processed 14.

Subsequently, the film to be processed 14 is processed by using the resist pattern 50 from which a residual film under the pattern is removed and PS as masks, and known process steps are performed, thereby obtaining a desired semiconductor device.

### Effect of First Embodiment

According to the first embodiment described above, since an exposure treatment and the like are unnecessary as compared to a method of forming a resist pattern on the shot lacking region 12, it is possible to improve a throughput and to suppress a semiconductor device production cost.

Also, according to the first embodiment described above, since it is possible to control the covering ratio of the shot lacking region 12 depending on the covering ratio of the shot region 10, it is possible to improve accuracy of finish dimension of the film to be processed 14 in the shot region 10.

Further, according to the first embodiment, since the covering ratio is controlled by using the plurality of types of block copolymers, not by using one type of block copolymer, it is possible to realize the covering ratio in addition to the covering ratio decided by one structure.

### Second Embodiment

A second embodiment is different from the first embodiment by the feature of controlling the covering ratios by using a plurality of block copolymers which becomes 3 structures by microphase separation. In the embodiments described below, configurations and functions which are the same as those of the first embodiment are denoted by reference numerals which are the same as those of the first embodiment, and descriptions thereof are not repeated.

### (Semiconductor Device Production Method)

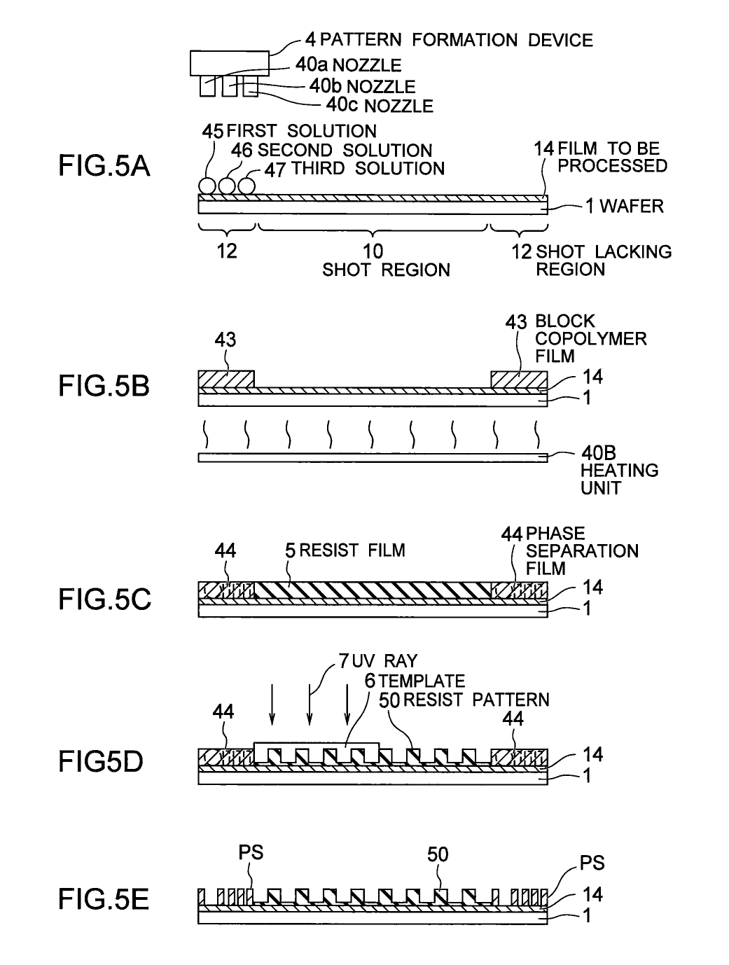

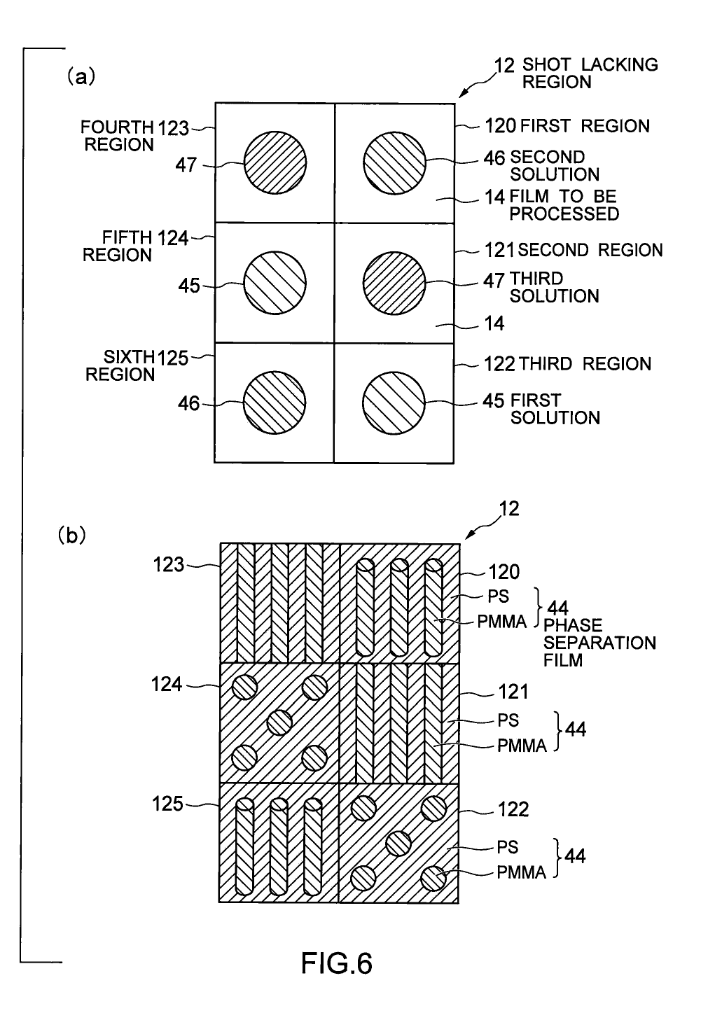

FIG. 5A to FIG. 5E are main part sectional views showing a semiconductor device production method according to the second embodiment. FIG. 6(a) is a block diagram showing a shot lacking region on which a solution containing the block copolymer is dropped according to the second embodiment. FIG. 6(b) is a block diagram showing a structure which is formed in the shot lacking region according to the second embodiment. In a shot lacking region 12 shown in FIGS. 6(a) and 6(b), at least one of first to sixth regions 120 to 125 is lacking.

In the present embodiment, a method for controlling a covering ratio of the shot lacking region 12 by changing composition ratios of PS and PMMA and by way of 3 different structures formed by microphase separation will be described. Block copolymers having inverted composition ratios may be used in combination.

A pattern formation device 4 according to the present embodiment includes, for example, nozzles 40a, 40b, and 40c depending on the type of the solution. The pattern formation device 4 is configured to supply one type of solution to a target region from each of the nozzles 40a, 40b, and 40c, for example.

To start with, a wafer 1 on which a film to be processed 14 is formed is prepared. Also, a first solution 45 for forming a spherical structure, a second solution 46 for forming a cylindrical structure, and a third solution 47 for forming a lamella structure by microphase separation are prepared.

Each of the first to third solutions 45 to 47 is obtained, for example, by dissolving a block copolymer into propylene glycol monomethyl ether acetate which is a solvent, and a concentration, a viscosity, and the like are adjusted so that the solutions 45 to 47 are emitted from the nozzles 40a, 40b, and 40c of the pattern formation device 4.

The first solution 45 forming the spherical structure has composition ratios of PS and PMMA of 80:20, for example. The second solution 46 forming the cylindrical structure has composition ratios of PS and PMMA of 70:30, for example. The third solution 47 forming the lamella structure has composition ratios of PS and PMMA of 50:50, for example.

Subsequently, as shown in FIG. 5A, the first solution 45, the second solution 46, and the third solution 47 are delivered by droplets onto the shot lacking region 12 from the nozzle 40a, the nozzle 40b, and the nozzle 40c, respectively. The pattern formation device 4 delivers, for example, by droplets any one of the solutions onto a predetermined region by a step-and-repeat method. The wafer 1 undergoes a hydrophobic treatment under HMDS atmosphere at 180° C. for 60 seconds so that a surface energy of the film to be processed 14 is adjusted. The surface energy of the film to be processed 14 may partially be adjusted depending on the type of the structure.

In the present embodiment, the first solution 45 is delivered by droplets onto the third and fifth regions 122 and 124, for example, as shown in FIG. 6(a). The second solution 46 is delivered by droplets onto the first and sixth regions 120 and 125, for example. The third solution 47 is delivered by droplets onto the second and fourth regions 121 and 123, for example.

Subsequently, the first to third solutions 45 to 47 delivered by droplets are spread on the shot lacking region 12.

Subsequently, a heat treatment is performed on the wafer 1 by a heating unit 40B as shown in FIG. 5B. The heat treatment is performed under nitrogen atmosphere at 220° C. for several minutes.

By the heat treatment, microphase separation is caused in a block copolymer film 43, and a phase separation film 44 including the spherical structure, the cylindrical structure, and the lamella structure is formed as shown in FIG. 6(b).

The cylindrical structure is generated in the first and sixth regions 120 and 125 as shown in FIG. 6(b). Each of PMMA regions of the first and sixth regions 120 and 125 shown in FIG. 6(b) is a structure which is formed of PMMA aggregated in a vertical direction from a surface of the film to be processed 14 and in the form of a column.

As shown in FIG. 6(b), the lamella structure is formed in each of the second and fourth regions 121 and 123. As shown in FIG. 6(b), the spherical structure is formed in each of the third and fifth regions 122 and 124. A dotted circle of a phase separation film 44 shown in each of FIG. 5C and FIG. 5D schematically indicates the sphere generated by the microphase separation. Also, dotted parallel lines in the phase separation film 44 schematically indicate the cylindrical structure or the lamella structure generated by the microphase separation.

Subsequently, a resist material is coated on the shot region 10 to form a resist film 5 as shown in FIG. 5C.

Subsequently, a resist pattern 50 is formed by the nanoimprint method as shown in FIG. 5D.

Subsequently, PMMA of the phase separation film 44 is removed by dry etching as shown in FIG. 5E.

In the third and fifth regions 122 and 124 onto which the first solution 45 is delivered by droplets, PMMA which is in the form of spheres is removed.

In the first and sixth regions 120 and 125 onto which the second solution 46 is delivered by droplets, PMMA which is in the form of cylinders is removed.

In the second and fourth regions 121 and 123 onto which the third solution 47 is delivered by droplets, PMMA is removed while remaining PS serving as a line-and-space pattern in which lines and spaces are aligned at predetermined equal intervals.

Subsequently, the film to be processed 14 is processed by using the resist pattern 50 from which a residual film under the pattern is removed and PS as masks, and known process steps are performed, thereby obtaining a desired semiconductor device.

### Effect of Second Embodiment

According to the second embodiment described above, it is possible to more accurately control the covering ratio of the shot lacking region 12 as compared to the case of inverting composition ratios of the block copolymers.

Also, according to the pattern formation device 4 according to the second embodiment described above, since the plurality of nozzles are provided corresponding to the types of solutions, it is possible to improve a throughput as compared to the device which delivers a plurality of solutions by droplets while cleaning a nozzle.

### Third Embodiment

A third embodiment is different from the foregoing embodiments by the feature of mixing and coating a plurality of types of block copolymers having different composition ratios.

In the present embodiment, a plurality of block copolymers to be a spherical structure, a cylindrical structure, a continuous structure, and a lamella structure are mixed to be coated on a shot lacking region 12.

Degrees of formation easiness of the structures are varied depending on, for example, a composition ratio, a molecular weight, a film thickness of a block copolymer film 43, a surface energy of a base layer, and the like. However, by forming a chemical guide on the base layer, it is possible to control the structures by microphase separation. The chemical guide is a region obtained by partially changing the surface energy of the base layer, for example. Alternatively, a crystal orientation may be used for the chemical guide.

When the chemical guide is hydrophobic and the block copolymer is formed of PS and PMMA, PS is aggregated on the chemical guide to generate a structure depending on the block copolymer around the chemical guide. Therefore, when coating a solution obtained by mixing a plurality of types of block copolymers, it is possible to control the formation of structures by forming chemical guides on the base layer depending on the structures to be formed.

### Effect of Third Embodiment

According to the third embodiment described above, since it is possible to coat the plurality of types of block copolymers after mixing the block copolymers, a throughput is improved as compared to the case of coating each of the plurality of types of block copolymers.

### Effects of Embodiments

According to the embodiments described above, since the pattern is formed by utilizing the microphase separation of the plurality of types of block copolymers, it is possible to improve a throughput and to suppress a production cost of the semiconductor device.

Though the pattern formation method by the nanoimprint method is employed in the foregoing embodiments, the pattern formation method is not limitative and may be replaced by photolithography, EUV (Extreme Ultra Violet) ray photolithography, or the like.

Also, in the foregoing embodiments, the coating of the solutions and the heat treatment are performed before the formation of the resist pattern, and one side of the block copolymer is removed after the formation of the resist pattern. However, the order may be reversed depending on the resist pattern formation method, the types of polymer block chains, or the like.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A pattern formation method comprising:
forming a first pattern in a first region on a substrate to be treated;
coating a plurality of types of block copolymers which are different in composition ratio on a second region, the second region being different from the first region; and
forming in the second region, by a heat treatment, a second pattern including a plurality of types of structures based on the coated plurality of types of block copolymers.

2. The pattern formation method according to claim 1, wherein
a covering ratio of the second pattern is decided based on a covering ratio of the first pattern of the first region adjacent to the second region.

3. The pattern formation method according to claim 1, wherein
a covering ratio of the second pattern is decided based on coating amounts and coating positions of the plurality of types of block copolymers.

4. The pattern formation method according to claim 1, wherein
the first region is a product region from which a product is obtained in the substrate to be treated, and the second region is a non-product region from which any product is not obtained in the substrate to be treated.

5. The pattern formation method according to claim 1, wherein
a surface of the substrate to be treated undergoes a hydrophobic treatment before the coating of the plurality of types of block copolymers.

6. The pattern formation method according to claim 1, wherein
each of the plurality of block copolymers is coated in the coating of the plurality of types of block copolymers on the second region.

7. The pattern formation method according to claim 1, wherein
each of the block copolymers is capable of microphase separation.

8. The pattern formation method according to claim 1, wherein
each of the block copolymers is obtainable by any one of combinations of polystyrene and polymethyl methacrylate, polystyrene and polydimethylsiloxane, polystyrene and polybutadiene, and polystyrene and polyisoprene.

9. The pattern formation method according to claim 1, wherein
each of the block copolymers includes a first polymer block chain and a second polymer block chain, and the first polymer block chain and the second polymer block chain are bonded by linear chemical bonding.

10. The pattern formation method according to claim 9, wherein
an etching rate of the first polymer block chain and an etching rate of the second polymer block chain are different from each other.

11. The pattern formation method according to claim 9, further comprising removing any one of the first polymer block chain and the second polymer block chain by etching after the heat treatment.

12. A pattern formation method comprising:
forming a first pattern in a first region on a substrate to be treated;
treating a predetermined portion among a second region in such a manner that the predetermined region has a surface energy which is different from that of other portions of the second region, the second region being different from the first region;
mixing and coating a plurality of types of block copolymers which are different in composition ratio on the second region; and
forming in the second region, by a heat treatment, a second pattern including a plurality of types of structures based on the coated plurality of types of block copolymers.

13. The pattern formation method according to claim 12, wherein
a covering ratio of the second pattern is decided based on a covering ratio of the first pattern of the first region adjacent to the second region.

14. The pattern formation method according to claim 12, wherein
the first region is a product region from which a product is obtained in the substrate to be treated, and the second region is a non-product region from which any product is not obtained in the substrate to be treated.

15. The pattern formation method according to claim 12, wherein
each of the block copolymers is capable of microphase separation.

16. The pattern formation method according to claim 12, wherein
each of the block copolymers includes a first polymer block chain and a second polymer block chain, and the first polymer block chain and the second polymer block chain are bonded by linear chemical bonding.

17. The pattern formation method according to claim 16, wherein
an etching rate of the first polymer block chain and an etching rate of the second polymer block chain are different from each other.

18. The pattern formation method according to claim 16, further comprising removing any one of the first polymer block chain and the second polymer block chain by etching after the heat treatment.

19. A pattern formation device comprising:
nozzles supplying a plurality of types of block copolymers which are different in composition ratio on a second region which is different from a first region on a substrate to be treated on which a first pattern is formed in the first region; and
a heating unit heating the substrate to be treated in order to form on the second region a second pattern including a plurality of types of structures based on the plurality of supplied block copolymers.

20. The pattern formation device according to claim 19, wherein the plurality of nozzles are provided corresponding to the types of the block copolymers to be supplied.
